(19) United States
(12) Patent Application Publication
(10) Pub. No.: US 2024/0351055 A1
(43) Pub. Date: Oct. 24, 2024

(54) ICP SOURCE GAS DELIVERY HUB AND NOZZLE

(71) Applicant: Applied Materials, Inc., Santa Clara, CA (US)

(72) Inventors: Yogananda Sarode Vishwanath, Bangalore (IN); Andrew Nguyen, San Jose, CA (US); Tom K. Cho, Los Altos Hills, CA (US)

(21) Appl. No.: 18/206,852

(22) Filed: Jun. 7, 2023

(30) Foreign Application Priority Data
Apr. 20, 2023 (IN) 202341028672

(51) Int. Cl. B05B 7/26; B05B 1/00; B05B 1/14; B05B 13/02; B33Y 80/00

(52) U.S. Cl. CPC B05B 7/26; B05B 1/005; B05B 1/14; B05B 13/0278; B33Y 80/00

(57) ABSTRACT

Example structures, methods, and systems for additive manufacturing of a gas hub and delivery nozzle are disclosed. One example structure includes a unitary gas hub and distribution nozzle that includes a gas hub portion and a gas delivery nozzle portion. The gas hub portion includes multiple gas inlet paths and one or more plenum chambers. The multiple gas inlet paths and the one or more plenum chambers form fully recursive gas paths. Each of the one or more plenum chambers has one or more output holes. The gas delivery nozzle portion includes multiple gas flow paths, where each gas flow path is coupled to one of the one or more output holes in each of the one or more plenum chambers, and each gas flow path has a respective output at an outer surface of the gas delivery nozzle portion.

### CROSS-REFERENCE TO RELATED APPLICATIONS

This application claims the benefit of priority under 35 U.S.C. § 119 to Indian patent application No. 202341028672, filed on Apr. 20, 2023, the contents of which are hereby incorporated by reference.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

Plasma processing systems include a gas delivery nozzle that distributes an etch gas mixture into a plasma processing chamber. This etch gas mixture is ignited using a plasma source to generate a plasma. Charged particles of the plasma are drawn towards an exposed surface of a substrate retained in the processing region of the chamber to perform an etching process on the exposed surface of the substrate.

The plasma is formed using a particular plasma source. One type of plasma source is an inductively coupled plasma (“ICP”) source. The ICP plasma source couples radio frequency energy to the etch gas mixture from the gas delivery nozzle using induction coils.

To deliver etch gases into the plasma processing chamber, one or more gas lines supply etch gases to a gas hub and delivery nozzle having one or more gas outlets into the plasma processing chamber. In some conventional systems, a gas delivery assembly includes separate gas hub and gas delivery nozzle components fitted together and configured to provide particular gas flow characteristics. O-rings can be incorporated into the gas delivery assembly to separate different gas regions of the gas hub and to provide gas seals between the gas hub and the gas delivery nozzle components.

In particular, the present specification describes technologies for a single gas hub and delivery nozzle for use in a plasma-based processing system. The single gas hub and delivery nozzle includes a hub portion and a delivery nozzle portion. The hub portion includes one or more plenums formed within the body of the hub. Each plenum of the one or more plenums is coupled to a respective set of gas flow paths of the delivery nozzle portion without need for any sealing O-rings between the hub portion and the delivery nozzle portion.

The gas hub and delivery nozzle can be formed as a single component using additive manufacturing techniques to design and fabricate the gas hub and delivery nozzle for use in plasma processing systems. In particular, a unitary gas hub and delivery nozzle is provided that uses additive manufacturing to combine the upper gas hub, bottom gas delivery nozzle, and one or more gas divider walls into a single component. In particular, by fabricating the one or more gas divider walls as part of the gas delivery nozzle structure, the need for gas sealing O-rings and alignment structures is eliminated.

Certain aspects of the subject matter described in this specification can be implemented as a structure embodied in a machine readable medium used in a design process. The structure includes a unitary gas hub and distribution nozzle that includes a gas hub portion and a gas delivery nozzle portion. The gas hub portion includes multiple gas inlet paths and one or more plenum chambers formed within a body of the gas hub portion, where the multiple gas inlet paths and the one or more plenum chambers form fully recursive gas paths. Each of the one or more plenum chambers has one or more output holes. The gas delivery nozzle portion includes one or more gas flow paths formed within a body of the gas delivery nozzle portion, where each gas flow path is coupled to one of the one or more output holes in each of the one or more plenum chambers, and each gas flow path has a respective output at an outer surface of the gas delivery nozzle portion. The structure can include one or more of the following features.

In some implementations, the structure resides on storage medium as a data format used for an exchange of layout data.

In some implementations, the structure includes at least one of test data files, characterization data, verification data, or design specifications.

In some implementations, each of the multiple gas inlet paths includes multiple branches, each of the multiple branches configured to provide input to a respective portion of a corresponding plenum chamber to provide uniform gas distribution.

In some implementations, the one or more plenum chambers include a first plenum chamber configured to direct etch gases to gas flow paths in the gas delivery nozzle portion having a first set of outputs and a second plenum chamber configured to direct etch gases to gas flow paths in the gas delivery nozzle portion having a second set of outputs.

In some implementations, the gas delivery nozzle portion includes multiple gas injection passages that couple the first plenum chamber to multiple nozzle outlets disposed at a bottom of the gas delivery nozzle portion and multiple gas injection passages that couple the second plenum chamber to multiple nozzle outlets disposed in a sidewall of the gas delivery nozzle portion

In some implementations, each of the first plenum chamber and the second plenum chamber includes one or more segments, each segment having a respective geometry formed within the body of the gas hub portion, where each segment is coupled to at least one gas inlet path of the multiple gas inlet paths and multiple output holes.

In some implementations, the unitary gas hub and distribution nozzle further includes one or more temperature monitoring sensors configured to monitor temperatures within the unitary gas hub and distribution nozzle.

Certain aspects of the subject matter described here can be implemented as a plasma processing system. The plasma processing system includes a unitary gas hub and distribution nozzle that includes a gas hub portion and a gas delivery nozzle portion. The gas hub portion includes multiple gas inlet paths and one or more plenum chambers formed within a body of the gas hub portion, where the multiple gas inlet paths and the one or more plenum chambers form fully recursive gas paths. Each of the one or more plenum chambers has one or more output holes. The gas delivery nozzle portion includes one or more gas flow paths formed within a body of the gas delivery nozzle portion, where each gas flow path is coupled to one of the one or more output holes in each of the one or more plenum chambers, and each gas flow path has a respective output at an outer surface of the gas delivery nozzle portion.

The plasma processing system can include one or more of the following features.

In some implementations, each of the multiple gas inlet paths includes multiple branches, each of the multiple branches configured to provide input to a respective portion of a corresponding plenum chamber to provide uniform gas distribution.

In some implementations, the one or more plenum chambers include a first plenum chamber configured to direct etch gases to gas flow paths of the gas delivery nozzle portion having a first set of outputs and a second plenum chamber configured to direct etch gases to gas flow paths of the gas delivery nozzle portion having a second set of outputs.

In some implementations, the unitary gas hub and distribution nozzle further includes one or more temperature monitoring sensors configured to monitor temperatures within the unitary gas hub and distribution nozzle.

Certain aspects of the subject matter described here can be implemented as a method. The method includes additively manufacturing a unitary gas hub and distribution nozzle. Additively manufacturing the unitary gas hub and distribution nozzle includes forming multiple layers including a gas delivery nozzle portion. Multiple layers including one or more gas flow paths within the gas delivery nozzle portion and having a defined geometry are formed. Multiple layers including a gas hub portion having one or more input gas ports for coupling to one or more corresponding gas lines are formed. Multiple layers including one or more plenum chambers and recursive gas flow paths within a body of the gas hub portion are formed. The gas hub portion further includes one or more output holes in each of the one or more plenum chambers. Each of the one or more gas flow paths in the gas delivery nozzle portion is coupled to one of the one or more output holes in each of the one or more plenum chambers, and each of the one or more gas flow paths has a respective output at an outer surface of the gas delivery nozzle portion.

The method can include one or more of the following features.

In some implementations, the one or more plenum chambers include a first plenum chamber configured to direct etch gases to gas flow paths in the gas delivery nozzle portion having a first set of outputs and a second plenum chamber configured to direct etch gases gas flow paths in the gas delivery nozzle portion having a second set of outputs.

In some implementations, each of the first plenum chamber and the second plenum chamber includes one or more segments, each segment having a respective geometry formed within the body of the gas hub portion, where each segment is coupled to at least one gas flow path of the recursive gas flow paths and multiple output holes.

The subject matter described in this specification can be implemented in these and other embodiments so as to realize one or more of the following advantages. An additively manufactured gas hub and delivery nozzle can retain the functions and performance of a gas hub and gas delivery nozzle formed from individually manufactured parts. The additively manufactured gas hub and delivery nozzle can also provide improved gas flow characteristics by having 3-D printed recursive gas flow path in the hub portion that provides more uniform and symmetric gas flow, and by eliminating gas sealing O-rings made as a separate part and from a different material than the upper gas hub. The gas sealing O-rings in a gas delivery nozzle with individually manufactured parts are no longer needed in a unitary hub and nozzle component because there are no joined parts that must be sealed from gas leaks. Removing the O-rings can eliminate issues such as tolerance play, floating parts, and particle generation that are associated with the gas sealing O-rings. By forming the gas delivery nozzle from additive manufacturing, uniformity and symmetry of gas flow in the gas delivery nozzle can be improved. Additionally, the additively manufactured gas delivery nozzle can reduce cost associated with machining waste, handle complex geometry associated with gas path, and shorten turn-around time and manufacturing steps. For example, different numbers, shapes, and configurations of gas flow paths can be designed and fabricated within the gas delivery nozzle portion though the additive manufacturing process. Additionally, the hub can be designed with different plenum structures including an additional number of gas isolated plenums and additional positioning relative to each other within the hub portion. Furthermore, additive manufacturing can simplify assembly, reduce alignment problems, and eliminate the need for various gas seals, e.g., O-rings, to deliver etch gases to the gas delivery nozzle.

Although the remaining disclosure will identify specific additively manufactured structures using the disclosed technology, it will be readily understood that the structures are equally applicable to a variety of other structures as can occur in the described gas hub and delivery nozzle. Accordingly, the technology should not be considered to be so limited as for use with the described structures alone. The disclosure will discuss one possible structure that can be used with the present technology before describing structures according to some embodiments of the present technology. It is to be understood that the technology is not limited to the structures described, and structures discussed can be used in any number of gas delivery components.

### BRIEF DESCRIPTION OF DRAWINGS

FIG. 1 illustrates a schematic cross-sectional view of an example plasma processing chamber.

FIGS. 2A to 2E illustrate a cross-sectional view of an example gas hub and delivery nozzle that is formed from a single structure, as well as embodiments of different portions of the example gas hub and delivery nozzle.

FIG. 3 illustrates a cross-sectional view of a hub portion of an example gas hub and delivery nozzle.

FIG. 4 illustrates a cross-sectional view of a hub portion of another example gas hub and delivery nozzle.

FIG. 5 illustrates a cross-sectional view of a hub portion of another example gas hub and delivery nozzle.

FIGS. 6A to 6E illustrate cross-sectional views of example gas hub and delivery nozzles that are each formed from a single structure.

FIG. 7 illustrates a flow diagram of an example process for manufacturing a gas hub and delivery nozzle.

FIG. 8 is a schematic illustration of an example computing system that can be used to execute implementations of the present disclosure.

Like reference numbers and designations in the various drawings indicate like elements.

### DETAILED DESCRIPTION

This specification relates to structures, methods, and systems for additively manufactured gas hub and delivery nozzles for inductively coupled plasma source based processing systems. The additively manufactured gas hub and delivery nozzle provided a unitary structure that provides the functions of both the hub and nozzle including forming one or more plenums in a body of the hub configured to receive input etch gases and to distribute the etch gases from each of the one or more plenums into a respective set of gas flow paths of the gas delivery nozzle.

An additively manufactured gas hub and delivery nozzle can retain the functions and performance of a gas delivery nozzle having individually manufactured parts. The additively manufactured gas hub and delivery nozzle can also provide improved gas flow characteristics by having 3-D printed recursive gas flow path that provides more uniform and symmetric gas flow, and by eliminating gas sealing O-rings made as a separate part and from a different material than the gas hub. Additionally, using additive manufacturing, gas hub and delivery nozzles can be configured with complex geometries including different arrangements of input and output gas flow paths, additional plenums formed within a body hub, and different gas path geometries within the gas nozzle portion. In some implementations, the combined gas hub and delivery nozzle are all formed from the same ceramic material such as aluminum oxide (alumina) or yttrium oxide (yttria). In some other implementations, a portion is formed from one material and a portion with another material. For example, the gas delivery nozzle portion can be formed from yttria using additive manufacturing and the gas hub portion can be formed from alumina using additive manufacturing.

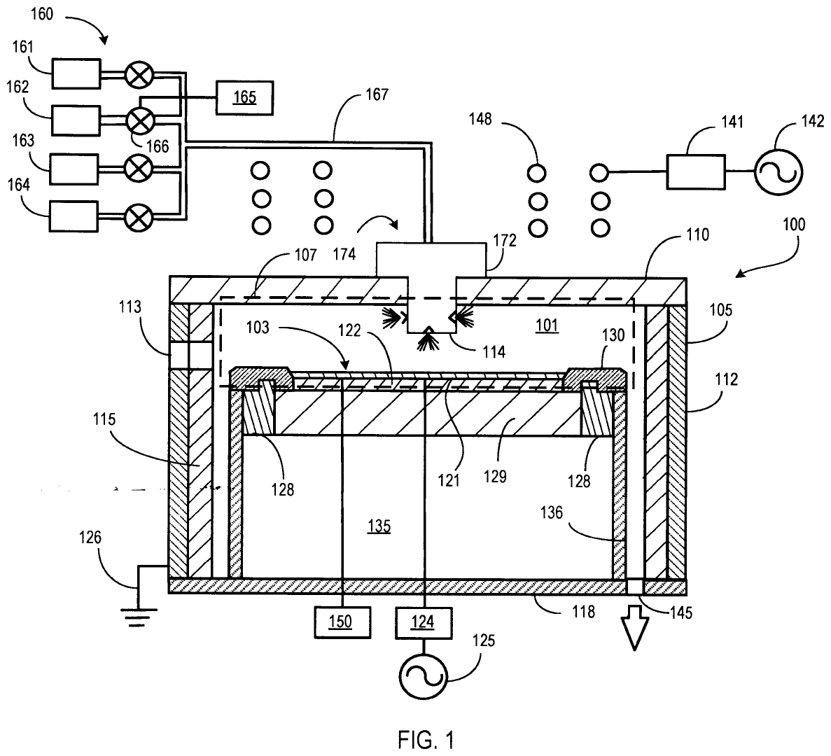

FIG. 1 illustrates an example 100 of a schematic cross-sectional view of a plasma processing chamber suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid assembly 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio-frequency (RF) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid assembly 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl3, C2F4, C4F8, C4F6, CHF3, CH2F2, CH3F, NF3, NH3, CO2, SO2, CO, N2, NO2, N2O, and H2, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid assembly 110 can include a gas delivery nozzle portion 114 of a combined gas hub and delivery nozzle 174. The gas delivery nozzle portion 114 can include one or more openings for introducing the process gases into the chamber volume 101. In particular, process gasses from the sources 161, 162, 163, 164 of the gas panel 160 pass to the gas hub portion 172 though gas line 167 and then into the gas delivery nozzle portion 114. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 103 and/or above the substrate 103 can be used to capacitively couple RF power to the process gases to maintain the plasma within the chamber volume 101. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some implementations, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

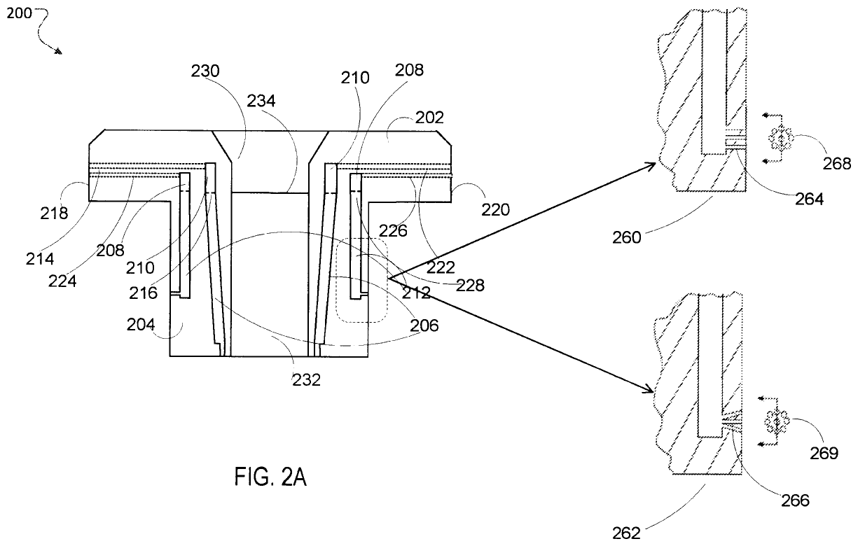

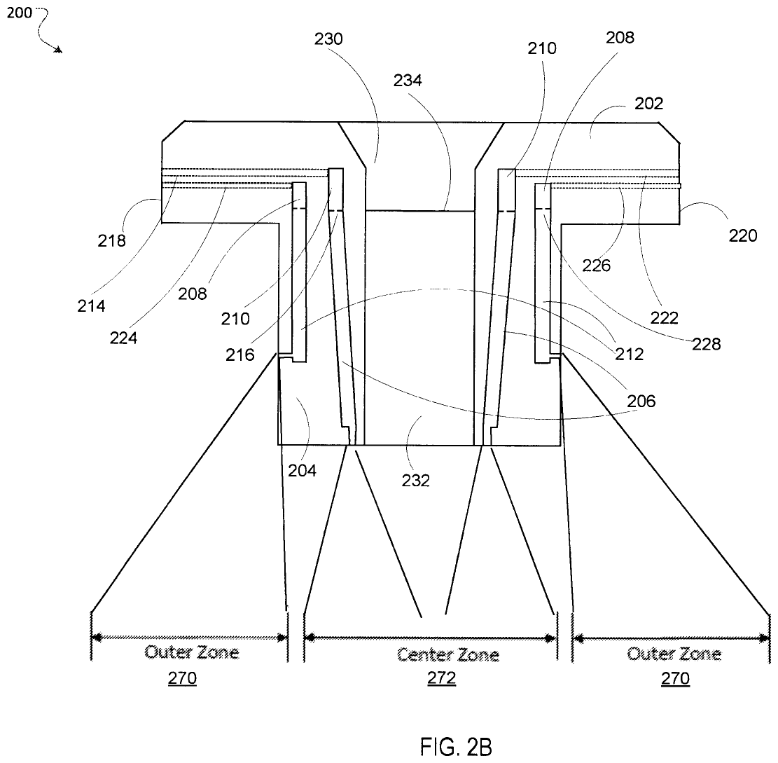

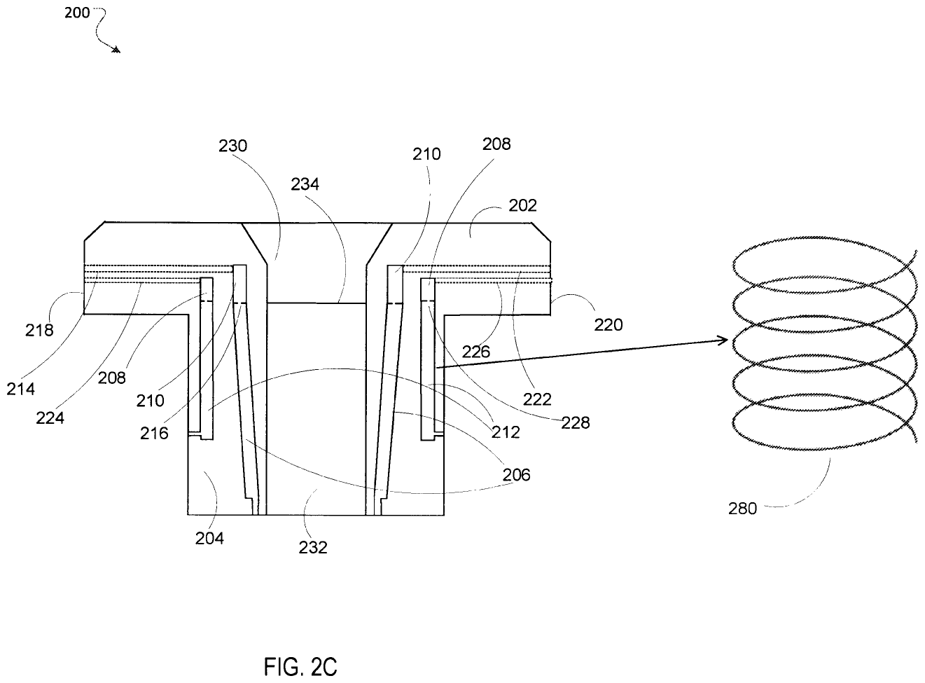

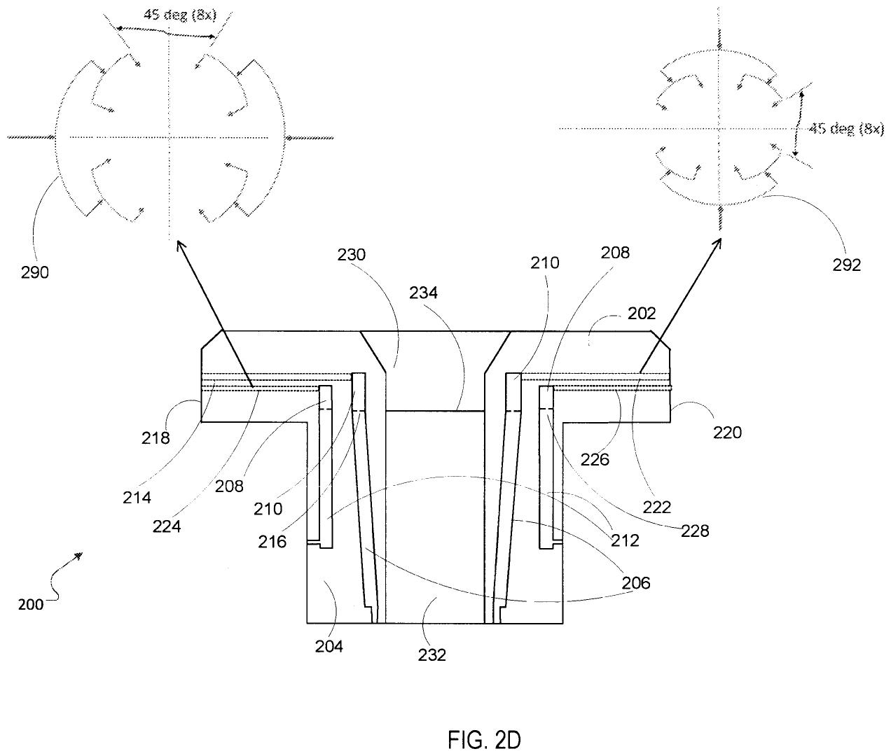

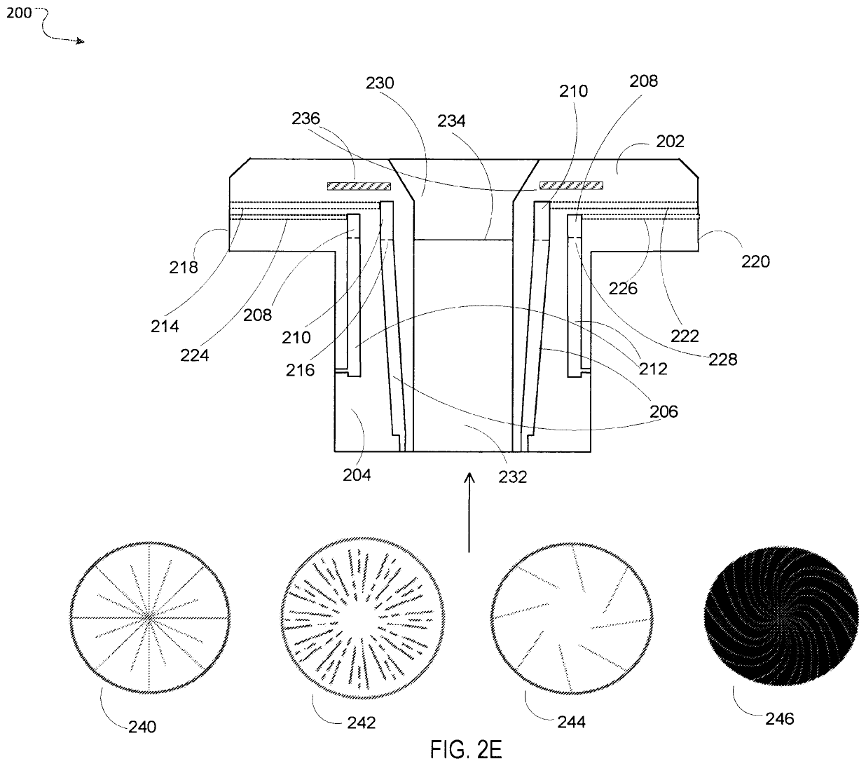

FIGS. 2A to 2E illustrate a cross-sectional view of an example gas hub and delivery nozzle 200 that is formed from a single structure, for example, using additive manufacturing, as well as embodiments of different portions of the example gas hub and delivery nozzle 200. In some implementations, gas hub and delivery nozzle 200 can be an embodiment of gas hub and delivery nozzle 174 in FIG. 1. Gas hub and delivery nozzle 200 includes a hub portion 202 and a nozzle portion 204. The nozzle portion 204 can have a cylindrical shaped body. Relative to a processing chamber, the nozzle portion 204 includes a section of the cylindrical body that is positioned within the processing chamber while the hub portion 202 is positioned outside of the processing chamber. Thus, for example, a chamber lid can be in contact with and surround a section of an outside surface of the nozzle portion 204 and the hub portion 202 may sit on a top surface of the chamber lid.

The gas hub portion 202 includes a central through hole 230 that extends through, and is aligned with, a corresponding through hole 232 of the nozzle portion 204. The gas hub and delivery nozzle 200 may include an observation window 234 at a particular location within the respective through holes, e.g., for use by one or more sensors monitoring a substrate within the processing region.

The hub portion includes an outer plenum chamber 208 and an inner plenum chamber 210. Each plenum chamber 208, 210 is configured to independently receive etch gases. The gas mixture and pressure supplied to one plenum chamber can therefore be independently controlled. The nozzle portion 204 includes a first set of gas outlets that are coupled to the inner plenum 210 and a second set of gas outlets that are coupled to the outer plenum 208. The first set of gas outlets, for example, can direct etch gases to a central region of the processing chamber for controlling an etch process on a central region of a substrate. Similarly, the second set of gas outlets can direct etch gases to an outer or edge region of the processing chamber for controlling an etch process on an edge region of a substrate.

Each plenum chamber can be formed from one or more segments that provide recursive gas paths. The respective plenum chambers can have different heights with respect to the cross section shown in FIG. 2A. For example, the inner plenum chamber 210 can have a greater height than the outer plenum chamber 208. The different heights allow for an inlet path, e.g., inlet path 214, to reach the inner plenum chamber 210 without interfering with the outer plenum chamber 208.

Each of the segments of the inner plenum chamber 210 is coupled to a single gas inlet of the hub portion 202 and to multiple gas outlets, e.g., gas outlet 216, which allow input etch gases to pass from the segment into one or more nozzle paths 206. Each of the one or more segments can provide a substantially uniform gas distribution and flow uniformity to the respective gas outlets 216.

Each of the segments of the outer plenum chamber 208 is coupled to a single gas inlet of the hub portion 202 and to multiple gas outlets, e.g., gas outlet 228, which allow input etch gases to pass from the segment into one or more nozzle paths 212. Each of the one or more segments can provide a substantially uniform gas distribution and flow uniformity to the respective gas outlets 228. Although FIG. 2A shows both nozzle paths 206 and 212, in some implementations, nozzle paths 212 can be in a different plane than nozzle paths 206, i.e., some cross sections of the gas hub and delivery nozzle 200 may intersect zero, one, or more of nozzle paths 206 or 212, depending on how nozzle paths 206 and 212 are positioned.

Each segment is coupled to a single gas inlet having a path from the segment and extending to a hub input, e.g., at the side of the hub portion 202. For example, in one implementation, the inner plenum chamber 210 can be formed from four separate segments. Two segments on a first side 218 of the hub portion 202 can be fed by separate inlet paths 214 entering from the first side 218 of the hub portion 202, while two segments on a second side 220 of the hub portion 204 can be fed by separate inlet paths 222 entering from the second side 220 of the hub portion 204. In another implementation, the outer plenum chamber 208 can be formed from four separate segments. Two segments on the first side 218 of the hub portion 202 can be fed by separate inlet paths 224 entering from the first side 218 of the hub portion 202, while two segments on the second side 220 of the hub portion 204 can be fed by separate inlet paths 226 entering from the second side 220 of the hub portion 204.

Each plenum chamber can have an annular shape as a single segment within the body of the hub portion 202. However, other shapes can be formed using the additive manufacturing process. When there are multiple segments for a given plenum chamber, each segment can be substantially arch shaped, straight, or serpentine. The shape of the segment can allow for variation in the outlet gas path locations, which can be used to provide a particular distribution of etch gases within the processing chamber.

Nozzle portion 204 includes multiple nozzle paths 206 that deliver, for example, through center nozzle outlets disposed at the bottom of the nozzle portion 204, gas from the inner plenum chamber 210 of the gas hub 202 to the processing chamber. In particular, each gas outlet 216 of the inner plenum chamber 210 is coupled to a distinct nozzle path 206.

Nozzle portion 204 can also include multiple nozzle paths 212 that deliver, for example, through side nozzle outlets disposed in the sidewall of the nozzle portion 204, gas from the outer plenum chamber 208 of the gas hub 202 to the processing chamber. In particular, each gas outlet 228 of the outer plenum chamber 208 is coupled to a distinct nozzle path 212.

FIG. 2A further illustrates an example side nozzle outlets in enlarged views 260, and 262, respectively. In enlarged view 260, side nozzle outlets 264 are coupled to nozzle path 212. Each side nozzle outlet 264 is substantially perpendicular to the nozzle path 212 and arranged in an array. For example, there can be nine side nozzle outlets 264 arranged as illustrated by array 268. In enlarged view 262, side nozzle outlets 266 are coupled to nozzle path 212. Each side nozzle outlet 266 has an angled intersection with the nozzle path 212 and are arranged in an array 269 in a similar pattern as array 268.

FIG. 2B illustrates example outer zone 270 of the processing chamber that is connected to nozzle paths 212 through side nozzle outlets disposed in the sidewall of the nozzle portion 204 and example center zone 272 of the processing chamber that is connected to nozzle paths 206 through center nozzle outlets disposed at the bottom of the nozzle portion 204. Nozzle paths 206 and 212, together with their corresponding center or side nozzle outlets, can deliver gas to different zones, for example, outer zone 270 and center zone 272 in the processing chamber, for improved tunability. In some implementations, the center zone 272 covers a circular area of a substrate being processed while the outer zone 270 covers a ring shaped area of the substrate surrounding the circular area of the center zone. However, other coverage zones are possible depending on the configuration of the nozzle outlets and the geometry of the substrate.

FIG. 2C illustrates an example helical nozzle path 280 that can be used and additively manufactured as nozzle path 206 or 212 in the nozzle portion 204. Other shapes of nozzle paths can also be used for nozzle path 206 or 212. The curved nozzle path 280, e.g., a helical tube, can avoid the direct line-of-sight from the plasma region to plenum chambers 208 and 210. The specific shape of nozzle path 206 or 212 depends on the number of holes directed towards the center zone 272 and the number of holes directed towards the outer zone 270. Helical nozzle path 280 can help increase conductance path when compared to linear nozzle paths. Complex nozzle paths such as helical nozzle path 280 can be additively manufactured when at least the delivery nozzle portion of the gas hub and delivery nozzle 200 is additively manufactured as a single structure.

FIG. 2D illustrates recursive gas flow paths 290 and 292 for inlet paths 224 and 222, respectively. Etch gases from gas ports can be directed to nozzle paths 212 and 206 respectively using recursive gas flow paths such as 290 and 292. Recursive gas flow paths 290 and 292 can split the gas distribution recursively to improve the uniformity of gas distribution within nozzle paths 206 and 212. For example, gas flow paths 290 start with a single inlet that is split twice to result in four total inputs to a corresponding plenum chamber. In some implementations, each pair of gas flow paths enter a corresponding plenum chamber at a 45 degree separation. In addition, these recursive gas flow paths can be 3D printed at different heights in the hub portion 202.

FIG. 2E illustrates four example nozzle outlet patterns 240, 242, 244, and 246 at the bottom of the nozzle portion 204. These nozzle outlets with different patterns can direct the etch gases to different portions of the processing chamber. In particular, at the endpoint of each nozzle path 206, at a surface of the nozzle portion 204, rather than just being a simple circular aperture, a particular nozzle outlet pattern can be formed. The outlet pattern can be the same for each nozzle path or one or more can be different. Example outlet patterns 240 and 242 show starburst style patterns. Example outlet pattern 244 shows a section of linear spiral sections while pattern 246 shows a spiral pattern. When the nozzle portion 204 is formed using additive manufacturing, these outlet patterns can be fabricated for each nozzle path during the additive manufacturing process.

FIG. 2E also illustrates two thermocouples 236 disposed in hub portion 202 when the gas hub and delivery nozzle 200 is additively manufactured. In some implementations, different sensors can be disposed in the hub portion 202 or the nozzle portion 204 to collect different measurements during the etching process. Temperature monitoring sensors such as thermocouples 236 can be disposed in the additively manufactured hub portion 202 or nozzle portion 204 to measure temperature inside the hub portion 202 or nozzle portion 204 during the etching process.

In some implementations, because the gas hub and nozzle 200 is formed from additive manufacturing as a unitary structure, the path from inlet to nozzle outlet can be formed without coupling components together. This eliminates the need for gas seals, e.g., O-rings, at different locations within the structure. Furthermore, the gas paths will be aligned as fabricated without possibility of misalignment of gas paths caused by coupling separate components together that may have variation in machining.

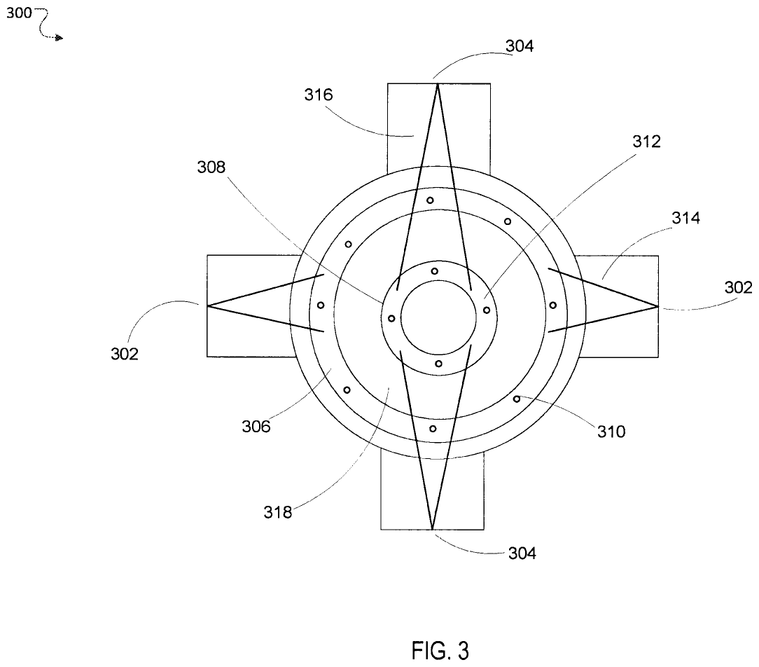

FIG. 3 illustrates a cross-sectional view 300 of the hub portion 202 of the gas hub and delivery nozzle 200 in FIG. 2A. Gas ports 302 can supply etch gases to the outer plenum 306 of the hub portion through gas path 314, which splits the gas distribution from each gas port 302 into two gas flow paths. While only two pairs of paths are shown for ease of illustration, each of the gas flow paths 314 can be further split into two gas flow paths, and this gas flow path splitting process can continue such that the uniformity of gas distribution within the outer plenum 306 can be improved. These split gas flow paths form a set of recursive gas flow paths to the outer plenum 208 in FIG. 2A, as illustrated in recursive gas flow path 290 in FIG. 2D and described above. In some implementations, one or more split gas flow paths are directed to particular segments of the outer plenum chamber 306 or to different portions of a single segment plenum chamber. Through additive manufacturing, each of these gas paths 314 can be fabricated to route gases to a specific location of the outer plenum 306 to provide a uniform gas distribution into the outer plenum 306.

Gas ports 304 can supply etch gases to the inner plenum chamber 312 of the hub portion through gas path 316. Recursive gas flow path in the inner plenum chamber can be formed in a way similar to that for the outer plenum chamber described above, such as recursive gas flow path 292 in FIG. 2D. Inner plenum chamber 312 and outer plenum chamber 306 can be separated by a gas divider wall, for example, gas divider wall 318. Outer plenum chamber 306 can distribute etch gases to side nozzle outlets disposed in the sidewall of the nozzle portion 204 of the gas hub and delivery nozzle 200 through nozzle paths 212 in FIG. 2A. Inner plenum chamber 312 can distribute etch gases to center nozzle outlets disposed at the bottom of the nozzle portion 204 of the gas hub and delivery nozzle 200 through nozzle paths 206 in FIG. 2A. Outlets 308 are coupled to center nozzle outlets disposed at the bottom of the nozzle portion 204 of the gas hub and delivery nozzle 200 through nozzle paths 206. Outlets 310 are coupled to side nozzle outlets disposed in the sidewall of the nozzle portion 204 of the gas hub and delivery nozzle 200 through nozzle paths 212. The side nozzle outlets allow for a particular distribution of gasses into the processing chamber. The position of each side nozzle outlet can vary along the sidewall of the nozzle portion 204 and there can also be more than one side nozzle outlet in the sidewall.

In some implementations, the etch gases and gas pressures can be independently controlled for each gas port in FIG. 3. As a result, the pressure and composition of etch gases within each plenum chamber can be independent. The independent control allows for more control over etch processes. For example, the center nozzle outlets disposed at the bottom of the nozzle portion of a gas hub and delivery nozzle can direct the etch gases to a portion of the processing chamber so that, when the etch gases are ionized into a plasma, charged particles are directed to a central region of a substrate. Similarly, the side nozzle outlets disposed in the sidewall of the nozzle portion of a gas hub and delivery nozzle can direct the etch gases to a portion of the processing chamber so that, when the etch gases are ionized into a plasma, charged particles are directed to an edge region of the substrate. The rate of etching may be different between the center region and edge region of the substrate. Independent plenum chambers for independently supplying etch gases can help provide for control of the etch rates to ensure consistent etching across the substrate.

Although FIG. 3 provides an example gas hub and delivery nozzle with two plenum chambers, other variations are possible. For example, more plenum chambers can be formed within the body of the hub portion, e.g., inner, middle, and edge plenum chambers. Each of these three plenum chambers can be independently supplied with etch gases for delivery into the processing chamber.

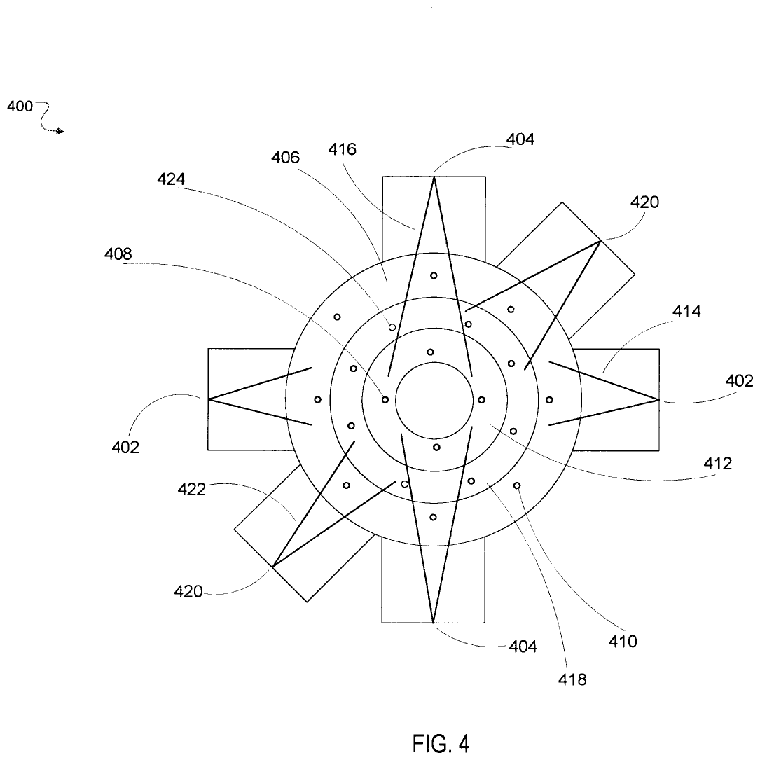

FIG. 4 illustrates a cross-sectional view of a hub portion of another gas hub and delivery nozzle. Similar to FIG. 3, FIG. 4 illustrates the mechanism of etch gas distribution from a gas port in the hub portion to one or more gas nozzle outlets of the nozzle portion through multiple gas paths in the nozzle portion that are coupled to a corresponding plenum chamber in the hub portion. For example, etch gases can pass from gas port 420 to central gas nozzle outlets at the bottom of the nozzle portion of a gas hub and delivery nozzle through gas paths 422 that are coupled to the middle plenum chamber 418, which has outlets 424 connected to central gas nozzle outlets at the bottom of the nozzle portion of a gas hub and delivery nozzle through nozzle paths, for example, the nozzle paths 206 in FIG. 2A. But unlike the hub portion in FIG. 3, which has two plenum chambers 306 and 312, the hub portion in FIG. 4 has three plenum chambers 406, 412, and 418. Each of the three plenum chambers 406, 412, and 418 has its own outlets coupled, through corresponding nozzle paths, to either the central gas nozzle outlets at the bottom of the nozzle portion of a gas hub and delivery nozzle or the side gas nozzle outlets in the sidewall of the nozzle portion of the gas hub and delivery nozzle.

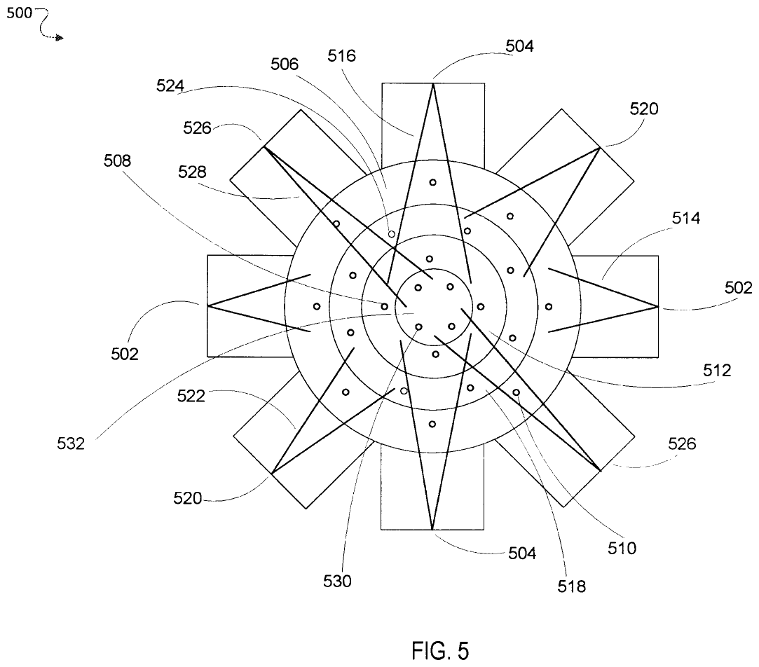

FIG. 5 illustrates a cross-sectional view of a hub portion of another gas hub and delivery nozzle. Similar to FIG. 4, FIG. 5 illustrates the mechanism of etch gas distribution from a gas port in the hub portion to one or more gas nozzle outlets of the nozzle portion through multiple gas paths in the nozzle portion that are coupled to a corresponding plenum chamber in the hub portion. For example, etch gases can pass from gas port 526 to central gas nozzle outlets at the bottom of the nozzle portion of a gas hub and delivery nozzle through gas paths 528 that are coupled to the innermost plenum chamber 532, which has outlets 530 connected to central gas nozzle outlets at the bottom of the nozzle portion of a gas hub and delivery nozzle through nozzle paths, for example, the nozzle paths 206 in FIG. 2A. But unlike the hub portion in FIG. 4, which has three plenum chambers 406, 412, and 418, the hub portion in FIG. 5 has four plenum chambers 506, 512, 518, and 532. Each of the four plenum chambers 506, 512, 518, and 532 has respective outlets coupled, through corresponding nozzle paths, to either the central gas nozzle outlets at the bottom of the nozzle portion of a gas hub and delivery nozzle or the side gas nozzle outlets in the sidewall of the nozzle portion of the gas hub and delivery nozzle.

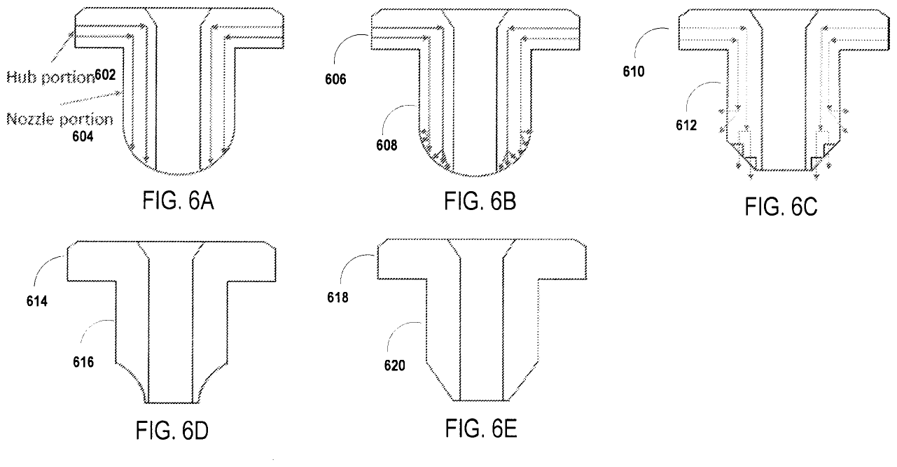

FIGS. 6A to 6E illustrate cross-sectional views of example gas hub and delivery nozzles that are each formed from a single structure. Each gas hub and delivery nozzle has its respective hub portion and nozzle portion, for example, 602 and 604 for FIG. 6A, 606 and 608 for FIG. 6B, 610 and 612 for FIG. 6C, 614 and 616 for FIG. 6D, and 618 and 620 for FIG. 6E. Each gas hub and delivery nozzle can have its own patterns of gas paths, such as those shown in FIGS. 6A to 6C. In particular, FIG. 6A shows linear gas paths and a curved nozzle tip. FIG. B shows gas paths that split into multiple outlet paths near the nozzle surface. FIG. 6C also shows gas paths split into multiple outlet paths, but with greater separation between respective outlet paths. An example curved nozzle end surface is illustrate in FIGS. 6A-C. Other nozzle shapes are possible. For example, FIG. 6D illustrates a nozzle tip having a flat end surface and perpendicular sidewalls joined by a concave surface. FIG. 6E shows a nozzle tip having a flat end surface and perpendicular sidewalls joined by an angled surface. Although not shown, FIGS. 6D and 6E can each have its own gas path patterns, such as those shown in FIGS. 6A to 6C.

As described above, the gas hub and delivery nozzle can be fabricated using additive manufacturing techniques. This allows for the formation of the gas hub and delivery nozzle as a single structure that eliminates the need for gas sealing O-rings that are used when a hub portion and a nozzle portion that are manufactured separately are assembled together to form a gas hub and delivery nozzle. For use in an ICP system, the gas hub and delivery nozzle 200 can be fabricated from dielectric materials, for example, alumina (e.g., Al2O3) or yttria (e.g., Y2O3). In some implementations, the gas hub and delivery nozzle is additively manufactured using alumina (e.g., Al2O3), then the exterior surface of the nozzle portion 204 that is exposed to plasma in the plasma processing chamber can be coated with yttria (e.g., Y2O3) after the gas hub and delivery nozzle is additively manufactured. This additional coating step can reduce the erosion from the plasma environment and extend the life of the gas hub and delivery nozzle. In some other implementations, the gas hub and delivery nozzle is additively manufactured using alumina (e.g., Al2O3) for the hub portion 202 and yttria (e.g., Y2O3) for the nozzle portion 204.

In some implementations, the entire structure of the gas hub and delivery nozzle is formed using additive manufacturing, e.g., including gas flow paths and output gas holes. In some other implementations, the additive manufacturing is augmented by subsequent manufacturing processes. For example, the nozzle portion 204 can be additively manufactured with a solid surface that is then processed to add output gas holes, e.g., by laser drilling. The gas hub and delivery nozzle formed through additive manufacturing can include one or more regions incorporating an infill pattern that reduces the material density within the structure while maintaining a specified level of strength and rigidity. Infill patterns can provide a repeating structure, e.g., a lattice structure, separated by hollow spaces, including, for example, a grid structure, triangle structure, etc.

In some implementations, a computer aided design (CAD) model of a gas hub and delivery nozzle is first made and then a slicing algorithm maps the information for every layer. A layer starts off with a thin distribution of powder spread over the surface of a powder bed. A chosen binder material then selectively joins particles where the gas hub and delivery nozzle is to be formed. Then a piston which supports the powder bed and the part-in-progress is lowered in order for the next powder layer to be formed. After each layer, the same process is repeated followed by a final heat treatment to make the gas hub and delivery nozzle. Since 3-D printing can exercise local control over the material composition, microstructure, and surface texture, various (and previously inaccessible) geometries may be achieved with this method.

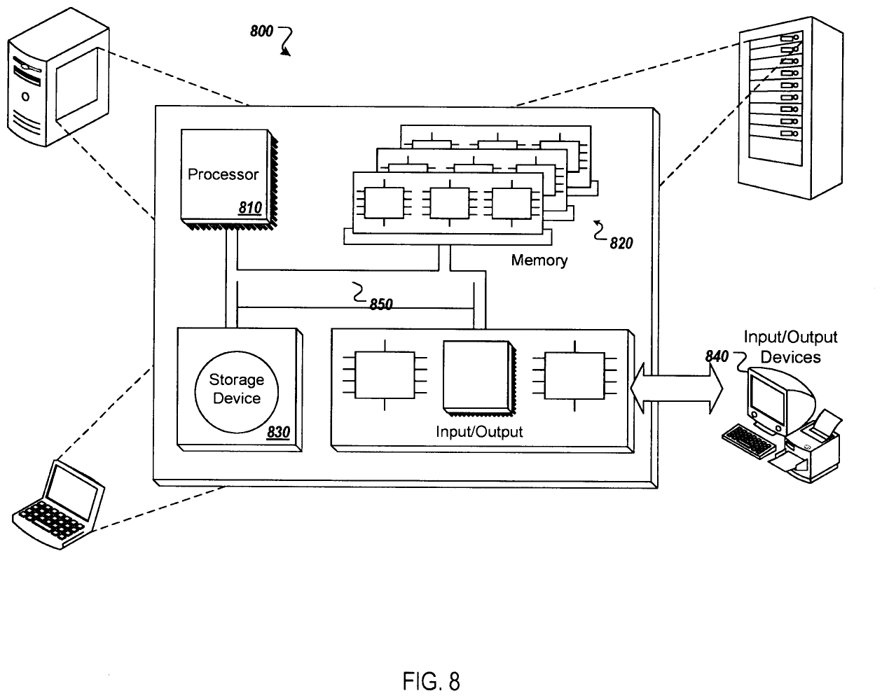

In some implementations, the gas hub and delivery nozzle as described in this specification may be represented in a data structure readable by a computer rendering device or a computer display device. FIG. 8 is a schematic illustration of an example computing system 800 that can be used to execute implementations of the present disclosure. In some implementations, memory 820 is a computer-readable medium that may contain a data structure that represents the gas hub and delivery nozzle. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the example computer system 400 to render the gas hub and delivery nozzle represented by the data structure on a computer screen or a physical rendering device which may be an additive manufacturing device, such as a 3-D printer.

In some implementations, additive manufacturing of a gas hub and delivery nozzle can avoid variations in manufacturing individual parts of the gas hub and delivery nozzle, as well as machining wastage, handling, and tooling associated with manufacturing individual parts of the gas hub and delivery nozzle. Using additive manufacturing also allows for less particle generation because the gas hub and delivery nozzle is manufactured as a single structure and the need for gas sealing O-rings is eliminated. Therefore there are no floating parts and associated tolerance play in the gas hub and delivery nozzle.

In some implementations, additively manufactured gas hub and delivery nozzle can handle complex geometry of recursive gas flow path within the hub portion. Additively manufactured gas hub and delivery nozzle can also handle different configurations of nozzle paths 206 and 212 in the nozzle portion, as well as the associated gas nozzle outlets disposed in the sidewall or at the bottom of the nozzle portion. Turn-around time and steps associated with manufacturing gas hub and delivery nozzles can be shortened using additive manufacturing. Additively manufacturing the gas hub and delivery nozzle can also resolve the issue associated with nozzle neck chipping or fall-off.

In some implementations, different sensors can be disposed in the hub portion 202 or the nozzle portion 204 to collect different measurements during the etching process. For example, temperature monitoring sensors such as thermocouples can be disposed in the additively manufactured hub portion 202 or nozzle portion 204 to measure temperature inside the hub portion 202 or nozzle portion 204 during the etching process. FIG. 2E illustrates two thermocouples disposed in hub portion 202 when the gas hub and delivery nozzle 200 is additively manufactured.

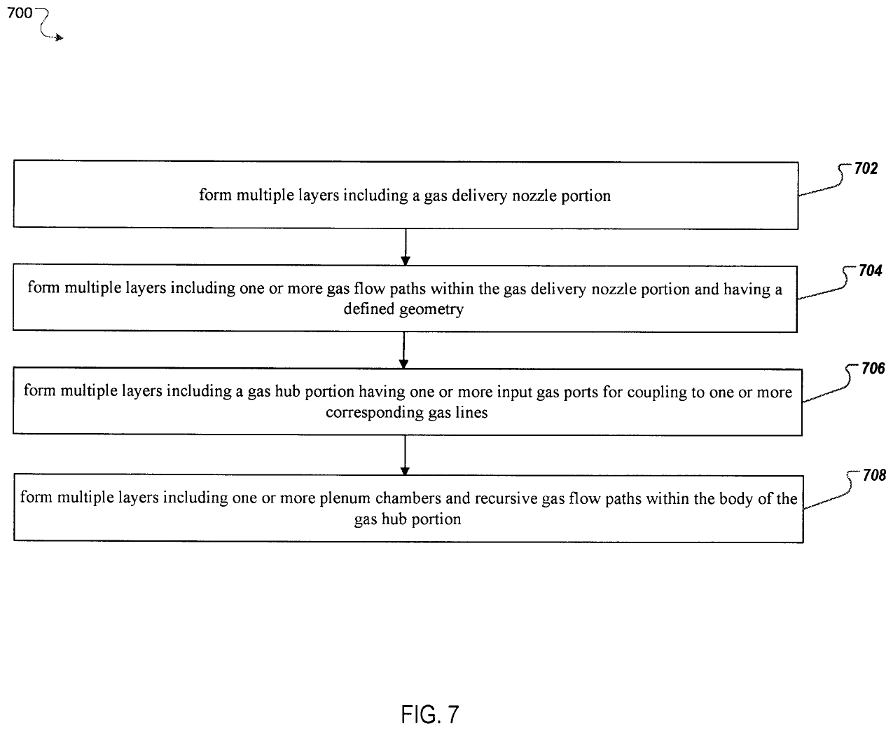

FIG. 7 illustrates a flow diagram of an example process 700 for manufacturing a gas hub and delivery nozzle, for example, for use in a plasma based processing system. For convenience, the process 700 will be described with respect to an additive manufacturing system that performs at least some steps of the process.

The additive manufacturing system forms multiple layers including a gas delivery nozzle portion (702). The additive manufacturing system can receive, from a computer system, a data structure representative of the gas delivery nozzle portion, and use the data structure to form the multiple layers of the gas delivery nozzle portion.

The additive manufacturing system forms multiple layers including one or more gas flow paths within the gas delivery nozzle portion and having a defined geometry (704). The one or more gas flow paths can correspond to nozzle outputs described above with respect to FIGS. 2A-4. In particular, an outlet hole on an outer surface of the gas delivery nozzle portion can be formed for respective gas flow paths that intersect with a bottom or sidewall of the gas delivery nozzle portion. Each of the one or more gas flow paths extends to a top portion of the gas delivery nozzle portion. The one or more gas flow paths can be formed in the shape of various three dimensional geometries. Furthermore, a cross-section of each gas flow path can have a specified geometry including, for example, circular, helical, square, “U” shaped, or trapezoidal.

The additive manufacturing system forms multiple layers including a gas hub portion having one or more input gas ports for coupling to one or more corresponding gas lines (706). The additive manufacturing system can receive, from the computer system, a data structure representative of the gas hub portion, and use the data structure to form the multiple layers of the gas hub portion. The layers of the gas hub portion can be additively formed as a continuation of the top surface of the gas delivery nozzle portion.

The additive manufacturing system forms multiple layers including one or more plenum chambers and recursive gas flow paths within the body of the gas hub portion (708). The one or more plenum chambers are formed with output holes that each couple to a gas flow path of the gas delivery nozzle portion. One or more paths lead from an input port aperture in the gas hub portion to a particular plenum chamber, as described above.

The multiple layers can be formed in a different direction. For example, the multiple layers can be formed in a reverse order in which the multiple layers forming the gas hub portion are formed first by the additive manufacturing system. The gas delivery nozzle portion can then be additively formed on the gas hub portion.

FIG. 8 illustrates a schematic diagram of an example computing system 800. The system 800 can be used for the operations described in association with the implementations described herein. For example, the system 800 may be included in any or all of the computing systems discussed herein. The system 800 includes a processor 810, a memory 820, a storage device 830, and an input/output device 840. The components 810, 820, 830, and 840 are interconnected using a system bus 850. The processor 810 is capable of processing instructions for execution within the system 800. In some implementations, the processor 810 is a single-threaded processor or a multi-threaded processor. The processor 810 is capable of processing instructions stored in the memory 820 or on the storage device 830 to display graphical information for a user interface on the input/output device 840.

The memory 820 stores information within the system 800. In some implementations, the memory 820 is a computer-readable medium. The memory 820 is a volatile memory unit. The memory 820 is a non-volatile memory unit. The storage device 830 is capable of providing mass storage for the system 800. The storage device 830 is a computer-readable medium. The storage device 830 may be a floppy disk device, a hard disk device, an optical disk device, or a tape device. The input/output device 840 provides input/output operations for the system 800. The input/output device 840 includes a keyboard and/or pointing device. The input/output device 840 includes a display unit for displaying graphical user interfaces.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A structure embodied in a machine readable medium used in a design process, the structure comprising:
a unitary gas hub and distribution nozzle comprising:
a gas hub portion comprising:
a plurality of gas inlet paths and one or more plenum chambers formed within a body of the gas hub portion, wherein the plurality of gas inlet paths and the one or more plenum chambers form fully recursive gas paths; and
one or more output holes in each of the one or more plenum chambers; and
a gas delivery nozzle portion comprising one or more gas flow paths formed within a body of the gas delivery nozzle portion, wherein each gas flow path is coupled to one of the one or more output holes in each of the one or more plenum chambers, and wherein each gas flow path has a respective output at an outer surface of the gas delivery nozzle portion.

2. The structure of claim 1, wherein the structure resides on storage medium as a data format used for an exchange of layout data.

3. The structure of claim 1, wherein the structure includes at least one of test data files, characterization data, verification data, or design specifications.

4. The structure of claim 1, wherein the gas hub portion is formed from a first dielectric material.

5. The structure of claim 4, wherein the gas delivery nozzle portion is formed from one of the first dielectric material or a second dielectric material different from the first dielectric material.

6. The structure of claim 1, wherein each of the plurality of gas inlet paths comprises multiple branches, each of the multiple branches configured to provide input to a respective portion of a corresponding plenum chamber to provide uniform gas distribution.

7. The structure of claim 4, wherein an exterior surface of the gas delivery nozzle portion has a coating, and the coating is of a third material, and the third material is different than the first dielectric material.

8. The structure of claim 1, wherein the one or more plenum chambers comprise a first plenum chamber configured to direct etch gases to gas flow paths in the gas delivery nozzle portion having a first set of outputs and a second plenum chamber configured to direct etch gases to gas flow paths in the gas delivery nozzle portion having a second set of outputs.

9. The structure of claim 8, wherein the gas delivery nozzle portion comprises a plurality of gas injection passages that couple the first plenum chamber to a plurality of nozzle outlets disposed at a bottom of the gas delivery nozzle portion.

10. The structure of claim 9, wherein the gas delivery nozzle portion further comprises a plurality of gas injection passages that couple the second plenum chamber to a plurality of nozzle outlets disposed in a sidewall of the gas delivery nozzle portion.

11. The structure of claim 8, wherein each of the first plenum chamber and the second plenum chamber comprises one or more segments, each segment having a respective geometry formed within the body of the gas hub portion, wherein each segment is coupled to at least one gas inlet path of the plurality of gas inlet paths and a plurality of output holes.

12. The structure of claim 1, wherein the unitary gas hub and distribution nozzle further comprises one or more temperature monitoring sensors configured to monitor temperatures within the unitary gas hub and distribution nozzle.

13. The structure of claim 1, wherein at least one of the one or more gas flow paths is a non-linear path that prevents line-of-sight from a corresponding output at the outer surface of the gas delivery nozzle portion to a corresponding output hole in a corresponding plenum chamber.

14. A plasma processing system, comprising:
a unitary gas hub and distribution nozzle comprising:
a gas hub portion comprising:
a plurality of gas inlet paths and one or more plenum chambers formed within a body of the gas hub portion, wherein the plurality of gas inlet paths and the one or more plenum chambers form fully recursive gas paths; and
one or more output holes in each of the one or more plenum chambers; and
a gas delivery nozzle portion comprising one or more gas flow paths formed within a body of the gas delivery nozzle portion, wherein each gas flow path is coupled to one of the one or more output holes in each of the one or more plenum chambers, and wherein each gas flow path has a respective output at an outer surface of the gas delivery nozzle portion.

15. The plasma processing system of claim 14, wherein each of the plurality of gas inlet paths comprises multiple branches, each of the multiple branches configured to provide input to a respective portion of a corresponding plenum chamber to provide uniform gas distribution.

16. The plasma processing system of claim 14, wherein the one or more plenum chambers comprise a first plenum chamber configured to direct etch gases to gas flow paths of the gas delivery nozzle portion having a first set of outputs and a second plenum chamber configured to direct etch gases to gas flow paths of the gas delivery nozzle portion having a second set of outputs.

17. The plasma processing system of claim 14, wherein the unitary gas hub and distribution nozzle further comprises one or more temperature monitoring sensors configured to monitor temperatures within the unitary gas hub and distribution nozzle.

18. A method, comprising:
additively manufacturing a unitary gas hub and distribution nozzle, wherein additively manufacturing the unitary gas hub and distribution nozzle comprises:
forming multiple layers including a gas delivery nozzle portion;
forming multiple layers including one or more gas flow paths within the gas delivery nozzle portion and having a defined geometry;
forming multiple layers including a gas hub portion having one or more input gas ports for coupling to one or more corresponding gas lines; and
forming multiple layers including one or more plenum chambers and recursive gas flow paths within a body of the gas hub portion; wherein:
the gas hub portion further comprises one or more output holes in each of the one or more plenum chambers; and
each of the one or more gas flow paths in the gas delivery nozzle portion is coupled to one of the one or more output holes in each of the one or more plenum chambers, and each of the one or more gas flow paths has a respective output at an outer surface of the gas delivery nozzle portion.

19. The method of claim 18, wherein the one or more plenum chambers comprise a first plenum chamber configured to direct etch gases to gas flow paths in the gas delivery nozzle portion having a first set of outputs and a second plenum chamber configured to direct etch gases gas flow paths in the gas delivery nozzle portion having a second set of outputs.

20. The method of claim 19, wherein each of the first plenum chamber and the second plenum chamber comprises one or more segments, each segment having a respective geometry formed within the body of the gas hub portion, wherein each segment is coupled to at least one gas flow path of the recursive gas flow paths and a plurality of output holes.
